(19) United States
(12) Patent Application Publication
(10) Pub. No.: US 2004/0195689 A1
(43) Pub. Date: Oct. 7, 2004

(54) Butting contact structure and method incorporating with a silicide inserted between a contact region and a conductor for a small contact window

(76) Inventors: Chorng-Wei Liaw, Huwei Jen (TW); Ming-Jang Lin, Taiping Shiang (TW); Wei-Jye Lin, Chaujou Jen (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/832,303

(22) Filed: Apr. 27, 2004

Related U.S. Application Data
(62) Division of application No. 10/335,878, filed on Jan. 3, 2003.

(30) Foreign Application Priority Data
Jan. 30, 2002 (TW) 091101614

(51) Int. Cl. H01L 29/76; H01L 21/4763

(52) U.S. Cl. 257/754; 438/630; 438/647; 257/757

(57) ABSTRACT

A butting contact structure using a silicide to connect a contact region and a conductor and a method to manufacture the same are disclosed. The method comprises the steps of: forming a first area having a first conduction type and a second area having a second conduction type which is adjacent to the first area; forming a silicide to be in contact with the first and second areas; and depositing an insulating layer covering the first portion of the silicide; etching a contact window in the insulating layer for exposing a surface of the silicide; and forming a conductor filling in the contact window. The difficulty from the reduction of the contact window is overcome without altering the manufacturing process and the layer of masks. Moreover, the density and performance of the semiconductor element is improved.

### FIELD OF THE INVENTION

The present invention relates generally to a contact structure and method for semiconductor devices, and more particularly to a butting contact structure and method utilizing a silicide as an interconnection between a contact region and a conductor filled in a small contact window of a semiconductor device.

### BACKGROUND OF THE INVENTION

Conventional butting contact is utilized to reduce the area of a semiconductor device so as to increase the density of the circuit thereon, and it is widely used in power MOSFETs to increase the cell density and reduce the conduction resistor. Moreover, the saturation voltages of the collector and emitter can be reduced also and the possibility of the conduction of parasitic bipolar junction transistor thereof is decreased. In addition to the advantages for the power MOSFET, butting contact can further reduce the damage induced from latch-up when it is applied to insulated gate bipolar transistor (IGBT).

FIG. 1 is a cross-sectional view showing a typical butting contact structure. The MOS device 100 includes a P type substrate 102, on which N+ areas 104 and 106 and P+ area 108 adjacent to the N+ area 106 are formed and thus a channel region 110 is formed between the N+ areas 104 and 106 with a gate oxide 112 and a gate 114 having spacer 116 on its sides formed above the channel region 110. An insulator 118 covers the structure and contact windows 120 and 122 are formed in the insulator 118 to thereby expose the N+ areas 104 and 106 and the P+ area 108. A silicide 124 is filled in the contact window 120 to connect the metal 126 to the N+ area 104, and the silicide 128 filled in the contact window 122 is used to connect the metal 130 to the N+ area 106 and P+ area 108. The contact of the metal 126 and silicide 124 to the N+ area 104 is called a general contact, and the contact of the metal 130 and silicide 128 to the N+ area 106 and P+ area 108 is called a butting contact.

Although the butting contact has many advantages as in the above descrption, it becomes hard to be applied to samll contact windows resulted from the scale-down of the line width in advanced semiconductor processes. Therefore, it is desired a butting contact structure and method without altering the manufacturing process and the masks thereto to overcome the difficulties induced from the reduced size of contact window.

### SUMMARY OF THE INVENTION

Accordingly, one object of the present invention is to provide a butting contact structure and method incorporating with a silicide to resolve the problem in the applications to small contact windows.

According to the present invention, a butting contact structure for applications to semiconductor devices comprises a contact region including two adjacent areas of oppositive conductivity types with a silicide formed thereon to contact the two adjacent areas and covered a part thereof by an insulator that is formed with a contact window therethrough to expose a surface of the silicide thereto is electrically connected a conductor filled in the contact window.

Furthermore, a butting contact method comprises selectively forming a silicide on two adjacent areas of appositive conductivity types followed by depositig an insulator to cover a part of the silicide and etching a contact window in the insulator to expose a surface of the silicide, and filling a conductor in the contact window to electrically connect with the silicide.

In one aspect of the present invention, the silicide is formed by a salicide process.

The various objects and advantages of the present invention will be more readily understood from the following detailed description when read in conjunction with the appended drawing.

### BRIEF DESCRIPTION OF THE DRAWINGS

FIG. 1 is a cross-sectional view showing a conventional butting contact structure;

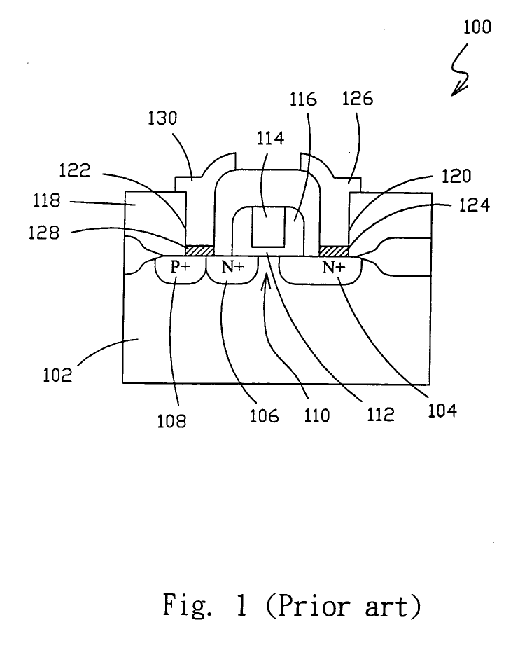

FIG. 2A is a cross-sectional view showing the invented butting contact structure applied to a CMOSFET;

FIG. 2B is a cross-sectional view showing a conventional CMOSFET with general contact thereof for comparison with the CMOSFET with the invented butting contact structure thereof shown in FIG. 2A;

FIG. 3A is a cross-sectional view showing the invented butting contact structure applied to a power MOSFET;

FIG. 3B is a cross-sectional view showing a conventional power MOSFET with conventional butting contact structure thereof for comparison with the power MOSFET with the invented butting contact structure thereof shown in FIG. 3A;

FIG. 4A is a cross-sectional view showing the invented butting contact structure applied to an IGBT;

FIG. 4B is a cross-sectional view showing a conventional IGBT with conventional butting contact structure thereof for comparison with the IGBT with the invented butting contact structure thereof shown in FIG. 4A;

FIG. 5 illustrates an embodiment process according to the present invention to form a CMOSFET, in which FIGS. 5A and 5B show the structures before and after a silicide is formed, FIG. 5C shows the structure after formed with an insulator and a contact window, and FIG. 5D shows the structure after a metal is formed to connect the silicide; and

FIG. 6 illustrates an embodiment process according to the present invention to form a power MOSFET, in which FIGS. 6A and 6B show the structures before and after a spacer is formed, FIG. 6C shows the structure after a silicide is formed, FIG. 6D shows the structure after formed with an insulator and a contact window, and FIG. 6E shows the structure after a metal is formed to connect the silicide.

### DETAILED DESCRIPTION OF THE INVENTION

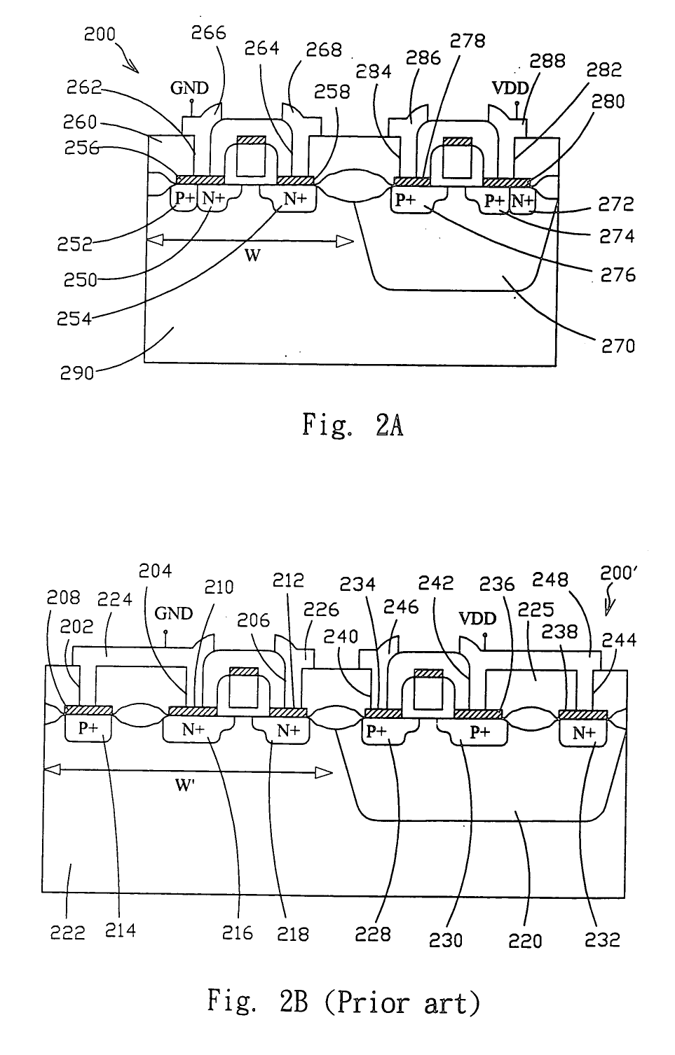

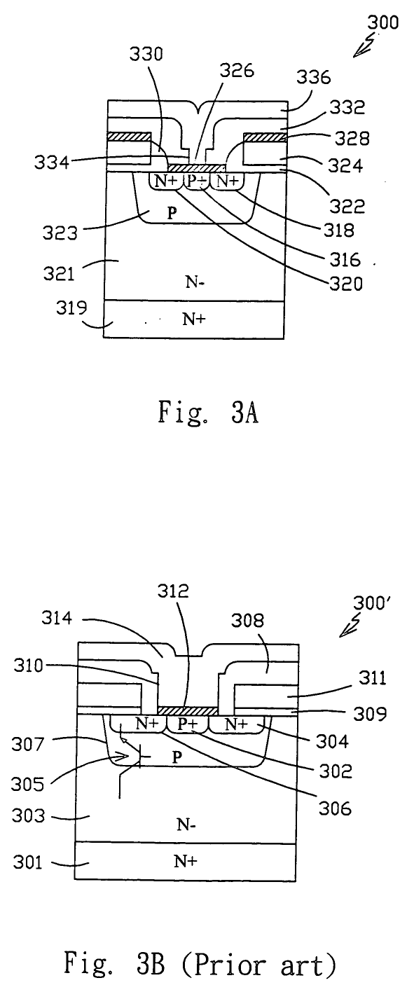

FIG. 2A is a cross-sectional view showing the invented butting contact structure applied to a CMOSFET. A device 200 includes an NMOS transistor structure and a PMOS transistor structure. In the NMOS transistor structure, on a P type substrate 290 are an N+ area 250 and a P+ area 252 adjacent to each another and an N+ area 254. The pMOS transistor structure is formed in an N type well 270, which includes an N+ area 272 and a P+ area 274 adjacent to each another and a P+ area 276. There are selectively formed a silicide 256 upon the N+ area 250 and P+ area 252, a silicide 258 upon the N+ area 254, a silicide 278 upon the P+ area 276, and a silicide 280 upon the N+ area 272 and P+ area 274. An insulator 260 covers the above structures, and contact windows 262, 264, 282 and 284 expose parts of the silicides 266, 258, 278 and 280, respectively. Metals 266, 268, 286 and 288 are further filled in the respective contact windows 262, 264, 282 and 284 to electrically connect the silicides 256, 258, 278 and 280, respectively.

FIG. 2B is a cross-sectional view showing a conventional CMOSFET device 200′ for comparison with the device 200 of FIG. 2A to illustrate the effects with butting contacts and without butting contacts. The transistor structure of the device 200′ is identical to the device 200 of FIG. 2A except that it is utilized general contact instead of butting contact. In particular, general contacts are utilized for the P+ area 214 and N+ areas 216 and 218 formed on a P type substrate 222, and P+ areas 228 and 230 and N+ area 232 formed in an N type well 220. In one embodiment utilizing 0.35 μm CMOS process and salicide process, the minimum width of a contact window is 0.4 μm. Under this conditions, the width W′ of the element in FIG. 2B is 4.35 μm, while the width W of the element in FIG. 2A is 2.85 μm. In other words, the use of butting contact can reduce the element scale up to 1.5 μm, i.e., a reduction ratio of 30%. In addition, the width of the well 270 in FIG. 2A can be smaller than that of the well 220 in FIG. 2B, since the element is sqeezed by use of the butting contact. The well resistance is thus also reduced due to such improvement.

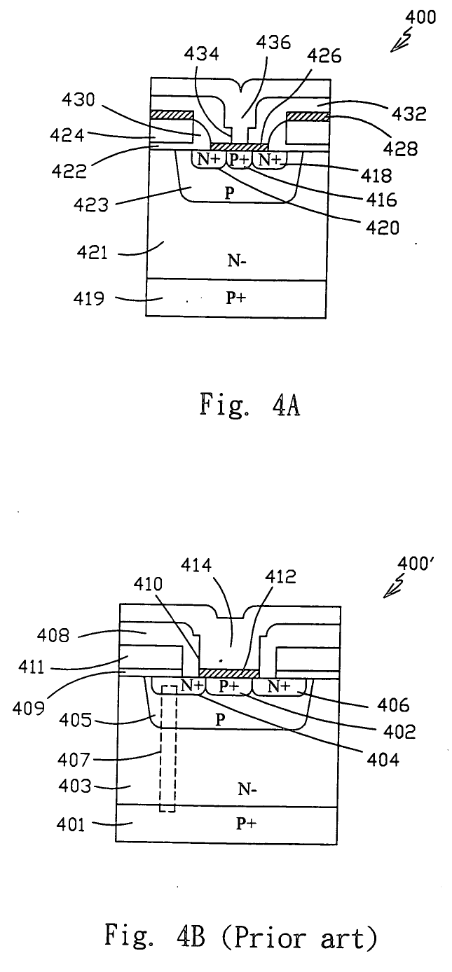

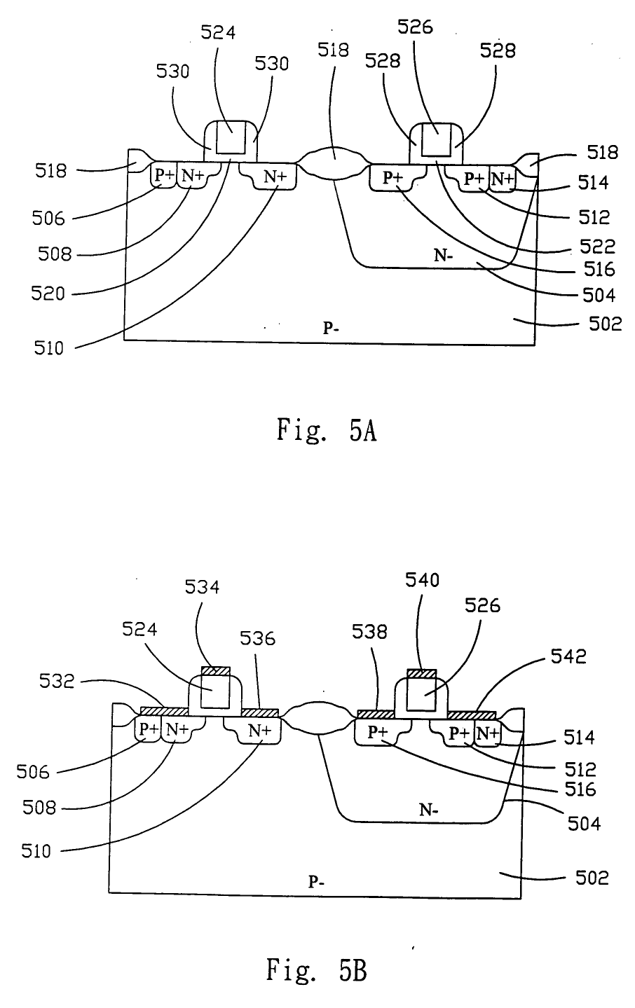

FIG. 3A is a cross-sectional view showing the invented butting contact structure applied to a power MOSFET. The device 300 has an N type substrate 319 and an N type expitaxial layer 321 formed on the N type substrate 319. A P type base 323 is formed in the N type expitaxial layer 321, and two N+ areas 318 and 320 and a P+ area 316 are formed in the P type base 323. The N+ areas 318 and 320 are surrounding and adjacent to the P+ area 316 in a power MOSFET. Above the base 323 at its sides are formed with gate oxides 322 and gates 324, and spacers 330 are formed on the sidewalls of the gates 324. By use of the spacers 330 as a mask, salicides 326 and 328 are formed on the P+ area 316, n+ areas 318 and 320 and the gates 324, respectively. An insulator 322 covers the structure, and a contact window 334 is formed in the insulator 332 to expose a part of the salicide 326. A metal 336 is filled in the contact window 334 to electrically connect the salicide 326.

FIG. 3B is a cross-sectional view showing a conventional power MOSFET device 300′ for comparison with the power MOSFET device 300 of FIG. 3A to illustrate the effects between the conventional and invented butting contacts. The device 300′ includes a P type substrate 301 with an N type expitaxial layer 303 formed thereon, and a P type base 307 formed in the N type expitaxial layer 303. Two N+ areas 304 and 306 and a P+ area 302 are formed in the P type base 307. The N+ areas 304 and 306 are surrounding and adjacent to the P+ area 307 as in a typical power MOSFET, and above the base 307 at its sides are formed with gate oxides 309 and gates 311. An insulator 308 covers the structure and a contact window 310 is formed in the insulator 308 to expose the P+ area 302 and a part of the N+ areas 304 and 306. A silicide 312 and a metal 314 are filled in the contact window 310 to contact the P+ area 302 and N+ areas 304 and 306. Compared with the structure shown in FIG. 3A, it is noted that the contact window 310 in FIG. 3B must be connected to the p+ area 302 and n+ areas 304 and 306. When the size of the contact window 310 is reduced, the contact window 310 can not or is difficult to be connected to the P+ area 302 and N+ areas 304 and 306 similtaneously. Further, since the line width is reduced, the alignment work becomes more difficult. As a result, the N+ areas 304 and 306 must be enlarged to provide a sufficient tolerance, and thereby the P type base 307 containing the N+ areas 304 and 306 must be enlarged. On the other hand, in such power MOSFET, a parasitic transistor 305 is existed between the N type expitaxial layer 303, P+ area 307 and N+ areas 304 and 306. Consequently, the butting contact structure in FIG. 3A can reduce the possibility of the conduction of the parasitic transistor thereof, in addition to the reduction of the element size, increasement of the cell density, and reduction of the conduction resistor.

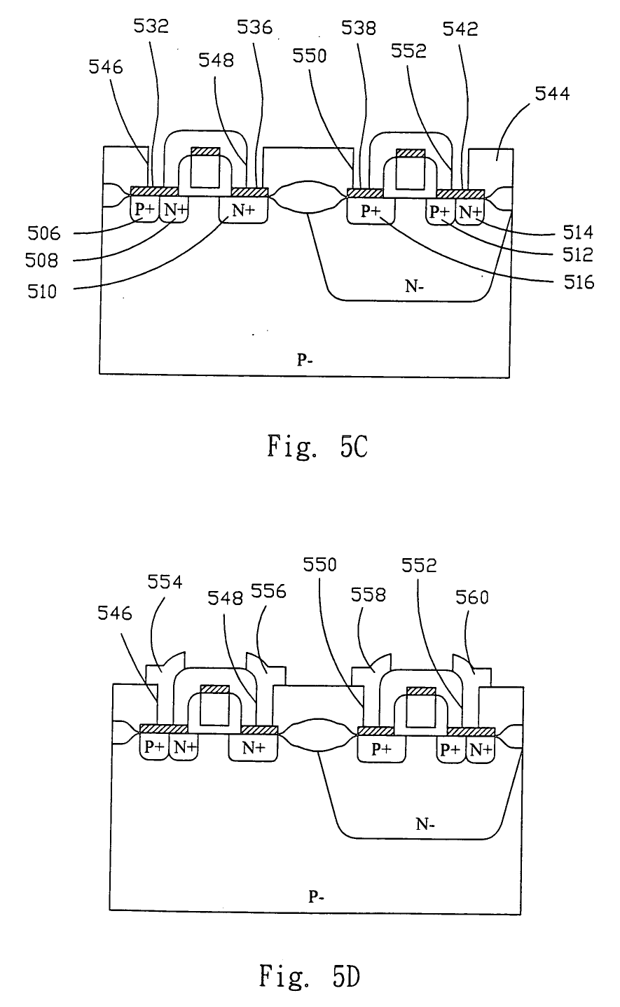

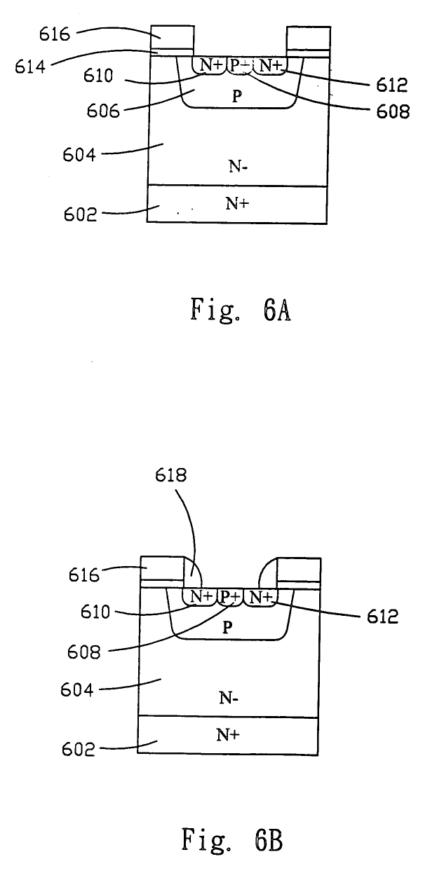

FIG. 4A is a cross-sectional view showing the invented butting contact structure applied to an IGBT whose structure is similar to that of the power MOSFET. The device 400 includes a P type substrate 419 and an N type expitaxial layer 421 formed thereon. A P type base 423 is formed in the N type expitaxial layer 421, and two N+ areas 418 and 420 and a P+ area 416 are formed in the P type base 423. The N+ areas 418 and 420 are surrounding and adjacent to the P+ area 416 in an IGBT. Above the base 423 at its sides are formed with gate oxides 422 and gates 424, and spacers 430 are formed on the sidewalls of the gates 424. By use of the spacers 430 as a mask, salicides 426 and 428 are formed on the P+ area 416, N+ areas 418 and 420 and the gates 324, respectively. An insulator 422 covers the structure, and a contact window 434 is formed in the insulator 332 to expose a part of the salicide 426. A metal 436 is filled in the contact window 434 to electrically connect the salicide 426.

FIG. 4B is a cross-sectional view showing a conventional IGBT device 400′ for comparison with the IGBT device 400 of FIG. 4A to illustrate the effects between the conventional and invented butting contacts. The device 400′ includes a P type substrate 401 with an N type expitaxial layer 403 formed thereon, and a P type base 405 formed in the N type expitaxial layer 403. Two N+ areas 404 and 406 and a P+ area 402 are formed in the P type base 405, and the N+ areas 404 and 406 are surrounding and adjacent to the P+ area 405 as in a typical IGBT. Above the base 405 at its sides are formed with gate oxides 409 and gates 411. An insulator 408 covers the structure and a contact window 410 is formed in the insulator 408 to expose the P+ area 402 and N+ areas 404 and 406. A silicide 412 and a metal 414 are filled in the contact window 410 to contact the P+ area 402 and N+ areas 404 and 406. Compared with the structure shown in FIG. 4A, the contact window 410 in FIG. 4B must be connected to the P+ area 302 and N+ areas 304 and 306. When the size of the contact window 410 is reduced, the contact window 410 can not or is difficult to be connected to the P+ area 402 and N+ areas 404 and 406 similtaneously. Further, since the line width is reduced, the alignment work becomes more difficult. As a result, the N+ areas 404 and 406 must be enlarged to provide a sufficient tolerance, and thereby the P type base 405 containing the N+ areas 404 and 406 must be enlarged. On the other hand, in such IGBT, a parasitic thyristor 407 is existed between the P type base 401, N type expitaxial layer 403, P+ base 405 and N+ areas 404 and 406. Consequently, the butting contact structure in FIG. 4A can reduce the possibility of the conduction of the parasitic thyristor thereof, in addition to the reduction of the element size, increasement of the cell density, and reduction of the conduction resistor.

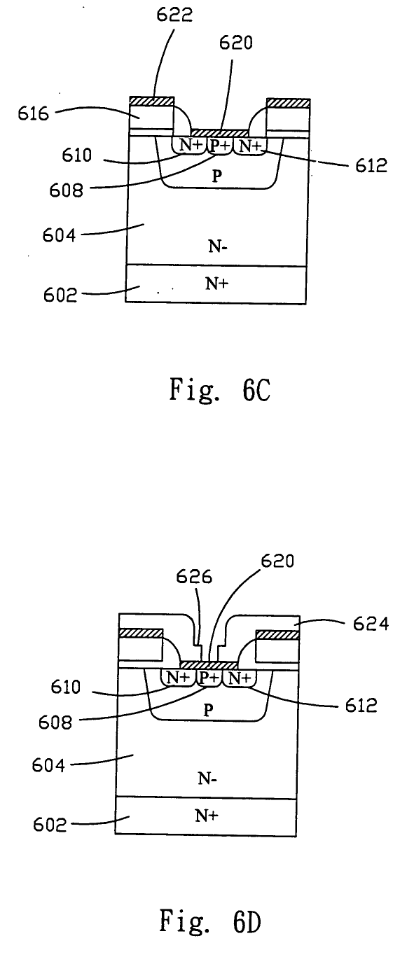

FIG. 5 illustrates an embodiment process according to the present invention to form a CMOSFET. As shown in FIG. 5A, in the initial structure, an N type well 504 is formed on a P type substrate 502. A P+ area 506, an N+ area 508 adjacent to the P+ area 506, and an N+ area 510 are formed in the P type substrate 502. A P+ area 512, an N+ area 514 adjacent to the P+ area 512, and P+ area 516 are formed in the N type well 504. Above and between the N+ areas 508 and 510 and the P+ areas 512 and 516 are formed with gate oxides 520 and 522 and gates 524 and 526, respectively, and spacers 530 and 528 are formed on the sidewalls of the gates 524 and 526, respectively. A field oxide 518 is formed to isolate the NMOS and PMOS. Then the spacers 528 and 530 and filed oxide 518 are used as a mask for a salicide process to form silicides 532, 536, 534, 542, 538 and 540 on the P+ area 506 and N+ area 508, N+ area 510, gate 524, P+ area 512 and N+ area 514, P+ area 516, and gate 526, respectively, as shown in FIG. 5B. As shown in FIG. 5C, an insulator 544 is deposited to cover the structure and etched through to form contact windows 546, 548, 550 and 552 to expose parts of the silicides 532, 536, 538 and 542. Then a metal layer is deposited and then etched to form metals 554, 556, 558 and 560 filled in the contact windows 546, 548, 550 and 552, as shown in FIG. 5D.

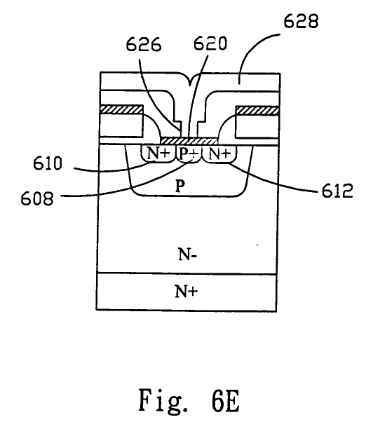

FIG. 6 illustrates an embodiment process according to the present invention to form a power MOSFET. As shown in FIG. 6A, in the initial structure, an N type expitaxial layer 604 is formed on an N type substrate 602, and a P type base 606 is formed in the N type expitaxial layer 604. A P+ area 608 and N+ areas 610 and 612 surrounding and adjacent to the P+ area 608 are formed in the P type base 606. Gate oxides 614 and gates 616 are formed above the P type well 606 at two sides. Next, as shown in FIG. 6B, spacers 618 are formed on the sidewalls of the gate oxides 614 and gates 616 to serve as a mask in the subsequent salicide process to form silicides 620 and 622 on the P+ area 608 and N+ areas 610 and 612, and gates 616, as shown in FIG. 6C. Then an insulator 624 is deposited and etched through to form a contact window 626 to expose a part of the salicide 620, as shown in FIG. 6D. Finally, a metal 628 is deposited and filled in the contact window 626 to electrically connect the salicide 620, as shown in FIG. 6E. The process to manufacture an IGBT according to the present invention is similar to that shown in FIG. 6, and thus the details will not be further described.

From the-above description, the silicide to interconnect a contact region and metal filled in a contact window in the invented butting contact structure is not filled in the contact window, and the contact window is thus only connected to a part of the silicide. Therefore, even the width of the contact window is dramatically reduced, the butting contact is still availble for the process. Further, the process is simplified since the contact window is only necessary to be aligned to any one part of the silicide instead to the contact region or both the adjacent areas of opposite conductivity types. According to the invented process, the contact window is formed after the silicide is formed and is only necessary to reach any one part of the silicide, the difficulties in alignment resulted from the reduced contact window are avoided subsequently. Moreover, the salicide process can be used, and therefore the advantages of simplification of manufacture process and minimization of elements can be maintained.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

1-3. (canceled).

4. A salicide butting contact structure comprising:
a contact region including a first area of a first conductivity type and a second area of a second conductivity type opposite to said first conductivity type surrouding and adjacent to said first area;
and contacting said first and second areas;
a second insulator covering said salicide;
a contact window formed in said second insulator and exposing a surface of said salicide; and
a conductor filled in said contact window and contacting said surface of said salicide.

5. A salicide butting contact structure of claim 4, wherein said first and second areas are heavily doped.

6. (canceled).

7. A butting contact method comprising the steps of:
forming a first area of a first conductivity type and a second area of a second conductivity type opposite to said first conductivity type and surrounding and adjacent to said first area;
forming a salicide by using a first insulator as a mask and contacting said first and second areas;
depositing a second insulator on said salicide;
etching a contact window in said second insulator and exposing a surface of said salicide; and
filling a conductor in said contact window and contacting said surface of said salicide.
